(19) United States
(12) Patent Application Publication
(10) Pub. No.: US 2006/0073705 A1
(43) Pub. Date: Apr. 6, 2006

(54) Method for dividing semiconductor wafer along streets

(75) Inventors: Kazuhisa Arai, Tokyo (JP); Shinichi Fujisawa, Tokyo (JP); Ryo Matsuhashi, Tokyo (JP); Takashi Ono, Tokyo (JP); Toshihiro Funanaka, Tokyo (JP); Jun Hachiya, Tokyo (JP); Akihito Kawai, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/237,690

(22) Filed: Sep. 29, 2005

(30) Foreign Application Priority Data
Oct. 6, 2004 (JP) 2004-293693

(51) Int. Cl. H01L 21/461

(52) U.S. Cl. 438/706

(57) ABSTRACT

A method for dividing a semiconductor wafer along a plurality of streets, the semiconductor wafer having a face on which a plurality of rectangular regions are defined by the streets arranged in a lattice pattern, and a semiconductor device is formed in each of the rectangular regions. This method comprises a protective member coating step of coating the face of the semiconductor wafer with a protective member, a resist film coating step of coating the back of the semiconductor wafer, except sites corresponding to the streets, with a resist film, and a plasma etching step of applying plasma etching to the back of the semiconductor wafer to divide the semiconductor wafer along the streets.

### FIELD OF THE INVENTION

This invention relates to a method for dividing a semiconductor wafer along streets, the semiconductor wafer having a face on which a plurality of rectangular regions are defined by the streets arranged in a lattice pattern, and a semiconductor device is formed in each of the rectangular regions.

### DESCRIPTION OF THE PRIOR ART

In the production of a semiconductor device, as is well known among those skilled in the art, the face of a semiconductor wafer, such as a silicon wafer, is partitioned into a plurality of rectangular regions by streets arranged in a lattice pattern, and a required semiconductor device is formed in each of the rectangular regions. Then, the semiconductor wafer is divided along the streets into the individual semiconductor devices. Usually, before the semiconductor wafer is divided along the streets, the back of the semiconductor wafer is ground to render the thickness of the semiconductor wafer sufficiently small. The division of the semiconductor wafer along the streets is performed by cutting the semiconductor wafer along the streets by use of a cutting edge in the form of a thin disk or an annular plate, which contains diamond grains, as disclosed in U.S. Pat. No. 6,345,616, or a laser beam as disclosed in U.S. Pat. No. 3,629,545.

However, the conventional method using a cutting edge or a laser beam poses the following problems: This method may cause damage, such as chipping, to the rectangular region when cutting the semiconductor wafer with the cutting edge or laser beam. Moreover, the cutting edge or laser beam needs to act on the semiconductor wafer along each of the plural streets. As a result, the efficiency of dividing the semiconductor wafer is not sufficiently high, and a relatively long time is required for division.

### SUMMARY OF THE INVENTION

It is a primary object of the present invention, therefore, to provide a novel and improved method which can divide the semiconductor wafer along the streets without incurring a possibility for causing damage, such as chipping, to the rectangular region.

In addition to attainment of the above primary object, it is another object of the present invention to provide a novel and improved method which can divide the semiconductor wafer along the streets with high efficiency.

The inventors diligently conducted studies, and have found that the primary object can be attained by utilizing plasma etching.

That is, according to the present invention, as a method for attaining the primary object, there is provided a method for dividing a semiconductor wafer along a plurality of streets, the semiconductor wafer having a face on which a plurality of rectangular regions are defined by the streets arranged in a lattice pattern, and a semiconductor device is formed in each of the rectangular regions.

the method comprising:

a protective member coating step of coating the face of the semiconductor wafer with a protective member;

a resist film coating step of coating a back of the semiconductor wafer, except sites corresponding to the streets, with a resist film; and

a plasma etching step of applying plasma etching to the back of the semiconductor wafer to divide the semiconductor wafer along the streets.

In the resist film coating step, it is preferred that the resist film is coated on the entire back of the semiconductor wafer, and then the resist film is removed partially at the sites corresponding to the streets. It is preferred to use a photoresist film as the resist film, expose the photoresist film at the sites corresponding to the streets, and then develop the photoresist film, thereby removing the photoresist film partially. A gas containing any one of SF₆, CF₄, C₂F₆, C₂F₄, and CHF₃ can be plasmatized, and used for the plasma etching. In a preferred embodiment, a resist film removal step of removing the resist film from the semiconductor wafer is included after the plasma etching step. In the resist film removal step, the resist film is preferably ashed. For the ashing, a gas containing oxygen can be plasmatized and used. A grinding step of grinding the back of the semiconductor wafer to decrease the thickness of the semiconductor wafer to a predetermined value can be included after the protective member coating step and before the resist film coating step. In this case, it is advantageous to include a damaged layer removal step of removing a damaged layer, which has been produced in the back of the semiconductor wafer by grinding the back of the semiconductor wafer, after the grinding step and before the resist film coating step.

### BRIEF DESCRIPTION OF THE DRAWINGS

FIG. 1 is a perspective view showing a typical example of a semiconductor wafer to which the method of the present invention is applied.

FIG. 2 is a partial sectional view showing a state in which a protective member has been affixed to the face of the semiconductor wafer of FIG. 1.

FIG. 3 is a partial sectional view showing a state in which the back of the semiconductor wafer of FIG. 2 has been ground to decrease the thickness of the semiconductor wafer.

FIG. 4 is a partial sectional view showing a state in which the entire back of the semiconductor wafer of FIG. 3 has been coated with a photoresist.

FIG. 5 is a partial sectional view showing a state in which sites of a photoresist film on the semiconductor wafer of FIG. 4, corresponding to streets, have been removed.

FIG. 6 is a partial sectional view showing a state in which plasma etching has been applied to the back of the semiconductor wafer illustrated in FIG. 5 to divide the semiconductor wafer along the streets.

FIG. 7 is a partial sectional view showing a state in which the photoresist film remaining on the back of the semiconductor wafer illustrated in FIG. 5 has been removed.

### DETAILED DESCRIPTION OF THE PREFERRED EMBODIMENTS

The preferred embodiments of the method constructed in accordance with the present invention will be described in detail with reference to the accompanying drawings.

FIG. 1 shows a semiconductor wafer 2 to which the preferred embodiment of the method of the present invention is applied. The semiconductor wafer 2, which is, for example, a silicon wafer, is disk-shaped as a whole, and a part of its edge is a straight edge 4 called an orientation flat. A plurality of streets 8 are arranged in a lattice pattern on the face 6 of the semiconductor wafer 2, and a plurality of rectangular regions 10 are defined by these streets 8. A semiconductor device (not shown) is formed in each of the rectangular regions 10.

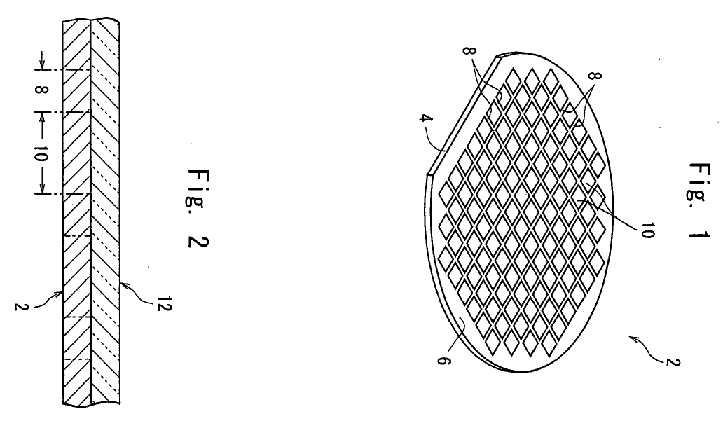

In the preferred embodiment of the method of the present invention, a protective member coating step is performed first. With reference to FIG. 2 along with FIG. 1, in this protective member coating step, a protective member 12, which may be a glass plate, a sheet or film of a suitable synthetic resin such as polyethylene terephthalate, or a suitable ceramic plate, is affixed onto the face 6 of the semiconductor wafer 2 via a suitable adhesive. The adhesive is preferably that of a type which is cured upon irradiation with infrared rays or ultraviolet rays or upon heating to decrease in or lose its adhesive action.

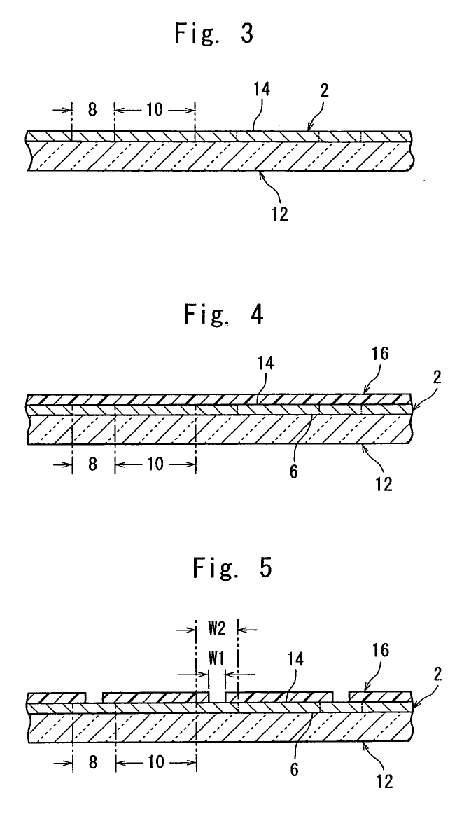

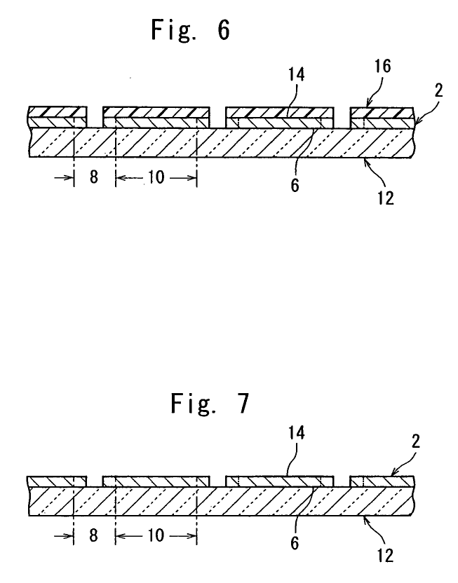

Then, a grinding step is performed preferably. In this grinding step, the back 14 of the semiconductor wafer 2 is ground, whereby the thickness of the semiconductor wafer 2 is sufficiently reduced as shown in FIG. 3. Grinding of the back of the semiconductor wafer 2 can be advantageously carried out, for example, by a grinder marketed under the trade name “DFG8540” by DISCO CORP. With such a grinder, a rotary grinding tool having a grinding piece containing diamond grains grinds the back of the semiconductor wafer 2.

As is well known among people skilled in the art, when the back 14 of the semiconductor wafer 2 is ground by the rotary grinding tool, machining-associated residual strain is generated by grinding, so that a damaged layer is produced in the back 14 of the semiconductor wafer 2. Such a damaged layer decreases the strength of the semiconductor wafer. Thus, it is desirable to perform a damaged layer removal step subsequently to the grinding step, thereby removing the damaged layer produced in the back 14 of the semiconductor wafer 2. The damaged layer produced in the back 14 of the semiconductor wafer 2 can be removed, for example, by polishing the back 14 of the semiconductor wafer 2 with a special polishing tool as disclosed in US-2002-0173244-A1, or by applying plasma etching to the back 14 of the semiconductor wafer 2 as disclosed in U.S. Pat. No. 6,511,895.

Then, a resist film coating step is performed. In the preferred embodiment of the method of the present invention, a photoresist film 16 is coated on the entire back 14 of the semiconductor wafer 2, as shown in FIG. 4. The photoresist film 16 itself may be one well known among those skilled in the art, and can be coated, for example, by a spinning method. Then, light is directed at the photoresist film 16 via a predetermined mask (not shown) to expose only sites corresponding to the streets 8 on the face 6 of the semiconductor wafer 2. Then, a developing solution is caused to act on the photoresist film 16, thereby dissolving and removing the photoresist film 16 at the exposed sites, namely, the sites corresponding to the streets 8 on the face 6 of the semiconductor wafer 2, as shown in FIG. 5. Preferably, the width w1 of the removed areas in the photoresist film 16 is substantially the same, or slightly smaller than, the width w2 of the street 8.

It is possible to coat the back 14 of the semiconductor wafer 2 with other resist film instead of the photoresist film 16, and remove only the required sites of the resist film, namely, the sites corresponding to the streets 8 on the face 6 of the semiconductor wafer 2, with the use of a tool such as a scribing tool or a cutting edge. Alternatively, it is permissible to coat required sites of the back 14 of the semiconductor wafer 2 with a masking agent having repellent characteristics against a resist film, and then coat the back 14 of the semiconductor wafer 2 with the resist film, thus rendering the resist film present on the back 14 of the semiconductor wafer 2, except the above-mentioned required sites. If desired, the resist film can be selectively coated only on portions other than the required sites in the back 14 of the semiconductor wafer 2.

In the method of the present invention, a plasma etching step is performed subsequently. In this plasma etching step, the semiconductor wafer 2 is accommodated in a plasma etching apparatus (not shown) of a suitable shape, such as a barrel type or a parallel flat plate type, where a plasmatized gas is caused to act on the back 14 of the semiconductor wafer 2. If the semiconductor wafer 2 is a silicon wafer, the plasmatized gas preferably contains any one of SF₆, CF₄, C₂F₆, C₂F₄, and CHF₃. In this plasma etching step, the semiconductor wafer 2 is etched throughout its thickness at the sites corresponding to the streets 8. In this manner, the semiconductor wafer 2 is divided along the streets 8. Plasma etching is not applied to the individual streets 8 one after another, but is applied to all the streets 8 simultaneously. Thus, the semiconductor wafer 2 can be divided along the streets 8 sufficiently efficiently. According to plasma etching, moreover, damage to the rectangular region 10, such as chipping, can be avoided sufficiently reliably.

In a preferred embodiment, a resist film removal step is performed subsequently to the plasma etching step and, in this resist film removal step, the photoresist film 16 is removed from the back 14 of the semiconductor wafer 2. Such a resist film removal step can be carried out advantageously by plasmatizing a gas containing oxygen, and causing the plasmatized gas to act on the photoresist film 16 remaining on the back 14 of the semiconductor wafer 2 to ash the photoresist film 16.

After the above-described resist film removal step, the adhesive action of the adhesive interposed between the face 6 of the semiconductor wafer 2 and the protective member 12 is decreased or eliminated by irradiation with infrared rays or ultraviolet rays, or by heating. Then, the individually separated rectangular regions 10, namely, semiconductor devices, are sequentially picked up from the protective member 12, and can be transported to required mounting positions.

While the preferred embodiments of the method constructed in accordance with the present invention have been described in detail by reference to the accompanying drawings, it is to be understood that the present invention should not be limited to such embodiments, but various changes and modifications may be made without departing from the scope of the present invention.

What we claim is:

1. A method for dividing a semiconductor wafer along a plurality of streets, said semiconductor wafer having a face on which a plurality of rectangular regions are defined by said streets arranged in a lattice pattern, and a semiconductor device is formed in each of said rectangular regions,
said method comprising:
a protective member coating step of coating the face of said semiconductor wafer with a protective member;
a resist film coating step of coating a back of said semiconductor wafer, except sites corresponding to said streets, with a resist film; and
a plasma etching step of applying plasma etching to the back of said semiconductor wafer to divide said semiconductor wafer along said streets.

2. The method according to claim 1, further comprising, in said resist film coating step, coating said resist film on a whole of the back of said semiconductor wafer, and then partially removing said resist film at the sites corresponding to said streets.

3. The method according to claim 2, wherein said resist film is a photoresist film, and which further comprises exposing said photoresist film at the sites corresponding to said streets, and then developing said photoresist film, thereby removing said photoresist film partially.

4. The method according to claim 1, wherein a gas containing any one of SF₆, CF₄, C₂F₆, C₂F₄, and CHF₃ is plasmatized, and used for said plasma etching.

5. The method according to claim 1, further comprising a resist film removal step of removing said resist film from said semiconductor wafer, after said plasma etching step.

6. The method according to claim 5, further comprising ashing said resist film in said resist film removal step.

7. The method according to claim 6, further comprising plasmatizing a gas containing oxygen, and using the plasmatized gas for said ashing.

8. The method according to claim 1, further comprising a grinding step of grinding the back of said semiconductor wafer to decrease a thickness of said semiconductor wafer to a predetermined value, after said protective member coating step and before said resist film coating step.

9. The method according to claim 8, further comprising a damaged layer removal step of removing a damaged layer, which has been produced in the back of said semiconductor wafer by grinding the back of said semiconductor wafer, after said grinding step and before said resist film coating step.
